(19) United States
(12) Patent Application Publication
(10) Pub. No.: US 2026/0089907 A1
(43) Pub. Date: Mar. 26, 2026

(54) BEOL SRAM Devices

(71) Applicant: Apple Inc., Cupertino, CA (US)

(72) Inventors: Saurabh P. Sinha, Austin, TX (US); Xin Miao, Saratoga, CA (US)

(21) Appl. No.: 19/336,163

(22) Filed: Sep. 22, 2025

Related U.S. Application Data
(60) Provisional application No. 63/697,667, filed on Sep. 23, 2024.

(51) Int. Cl. H10B 10/00; H10D 89/10

(52) U.S. Cl. CPC H10B 10/12; H10D 89/10

(57) ABSTRACT

Integrated circuit devices with memory circuits formed between topside BEOL (back end of line) metal layers are described. The memory circuits include active regions and source/drains that can be formed in the spaces between topside metal layers. In certain instances, the memory circuits are formed in between metal layers furthest away from substrate. The memory circuits connect to signal and power routing either above or below the transistors. In various instances, the active regions of the memory circuits are formed by thin channel materials.

### PRIORITY CLAIM

The present application claims priority to U.S. Provisional App. No. 63/697,667, entitled “BEOL SRAM Devices,” filed Sep. 23, 2024, the disclosure of which is incorporated by reference herein in its entirety.

### BACKGROUND

### Technical Field

Embodiments described herein relate to power and signal routing for semiconductor devices. More particularly, embodiments described herein relate to implementation of memory circuit transistors in topside metal layers such as BEOL (“back end of line”) metal layers.

### Description of the Related Art

Current trends in standard transistor device methodology are towards reducing the size of components and overall structures (e.g., standard cells) while increasing the complexity (e.g., circuit density and number of components). As structure designs become smaller, however, it becomes more difficult to provide access (e.g., connections) to components within the structures. Thus, there is a need for improvements in the placement of small power structures such as memory circuits. Additionally, placing memory circuits closer to functional transistors may provide processing improvements.

### BRIEF DESCRIPTION OF THE DRAWINGS

Features and advantages of the methods and apparatus of the embodiments described in this disclosure will be more fully appreciated by reference to the following detailed description of presently preferred but nonetheless illustrative embodiments in accordance with the embodiments described in this disclosure when taken in conjunction with the accompanying drawings in which:

FIG. 1 depicts a top view representation of a memory circuit that can be located in topside metal layers, according to some embodiments.

FIG. 2 depicts a top view representation of a contemplated device with the memory circuit of FIG. 1 positioned between two topside metal layers, according to some embodiments.

FIG. 3 is a cross-sectional side-view representation of a device showing a memory circuit along line 3-3 in FIG. 2, according to some embodiments.

FIG. 4 is a cross-sectional side-view representation of a device showing a memory circuit along line 4-4 in FIG. 2, according to some embodiments.

FIG. 5 is a cross-sectional side-view representation of a device showing a memory circuit along line 5-5 in FIG. 2, according to some embodiments.

FIG. 6 depicts a top view representation of another memory circuit that can be located in topside metal layers, according to some embodiments.

FIG. 7 depicts a top view representation of a contemplated device with the memory circuit of FIG. 6 positioned between two topside metal layers, according to some embodiments.

FIG. 8 is a cross-sectional side-view representation of a device showing a memory circuit along line 8-8 in FIG. 7, according to some embodiments.

FIG. 9 is a cross-sectional side-view representation of a device showing a memory circuit along line 9-9 in FIG. 7, according to some embodiments.

FIG. 10 is a cross-sectional side-view representation of a device showing a memory circuit along line 10-10 in FIG. 7, according to some embodiments.

FIG. 11 is a cross-sectional side-view representation of a device showing a memory circuit along line 11-11 in FIG. 7, according to some embodiments.

FIG. 12 depicts a top view representation of a contemplated device with yet another memory circuit positioned between two topside metal layers, according to some embodiments.

FIG. 13 depicts a bottom view representation of the contemplated device of FIG. 12, according to some embodiments.

FIG. 14 is a cross-sectional side-view representation of a device showing a memory circuit along line 14-14 in FIGS. 12 and 13, according to some embodiments.

FIG. 15 is a cross-sectional side-view representation of a device showing a memory circuit along line 15-15 in FIGS. 12 and 13, according to some embodiments.

FIG. 16 is a cross-sectional side-view representation of a device showing a memory circuit along line 16-16 in FIGS. 12 and 13, according to some embodiments.

FIG. 17 depicts a top view representation of a contemplated device with A memory circuit positioned between two topside metal layers and with a middle metal layer in the memory circuit, according to some embodiments.

FIG. 18 depicts a bottom view representation of the contemplated device of FIG. 17, according to some embodiments.

FIG. 19 is a cross-sectional side-view representation of a device showing a memory circuit along line 19-19 in FIGS. 17 and 18, according to some embodiments.

FIG. 20 is a cross-sectional side-view representation of a device showing a memory circuit along line 20-20 in FIGS. 17 and 18, according to some embodiments.

FIG. 21 is a cross-sectional side-view representation of a device showing a memory circuit along line 21-21 in FIGS. 17 and 18, according to some embodiments.

FIG. 22 is a cross-sectional side-view representation of a first manufacturing step of a memory circuit positioned between two topside metal layers, according to some embodiments.

FIG. 23 is a cross-sectional side-view representation of a second manufacturing step of a memory circuit positioned between two topside metal layers, according to some embodiments.

FIG. 24 is a cross-sectional side-view representation of a third manufacturing step of a memory circuit positioned between two topside metal layers, according to some embodiments.

FIG. 25 is a cross-sectional side-view representation of a fourth manufacturing step of a memory circuit positioned between two topside metal layers, according to some embodiments.

FIG. 26 is a cross-sectional side-view representation of a fifth manufacturing step of a memory circuit positioned between two topside metal layers, according to some embodiments.

FIG. 27 is a cross-sectional side-view representation of a sixth manufacturing step of a memory circuit positioned between two topside metal layers, according to some embodiments.

FIG. 28 is a cross-sectional side-view representation of a seventh manufacturing step of a memory circuit positioned between two topside metal layers, according to some embodiments.

FIG. 29 is a cross-sectional side-view representation of a final (eighth) manufacturing step of a memory circuit positioned between two topside metal layers, according to some embodiments.

FIG. 30 is a block diagram of one embodiment of an example system.

Although the embodiments disclosed herein are susceptible to various modifications and alternative forms, specific embodiments are shown by way of example in the drawings and are described herein in detail. It should be understood, however, that drawings and detailed description thereto are not intended to limit the scope of the claims to the particular forms disclosed. On the contrary, this application is intended to cover all modifications, equivalents and alternatives falling within the spirit and scope of the disclosure of the present application as defined by the appended claims.

### DETAILED DESCRIPTION OF EMBODIMENTS

The present disclosure is directed to the implementation of memory circuits (such as SRAM circuits) in between metal layers above a transistor region (e.g., topside metal layers) of integrated circuit devices. In various embodiments, these topside metal layers may be referred to as BEOL (“back end of line”) metal layers. The topside metal layers may provide routing (e.g., paths) for control signals and/or power signals. Many current designs of cells provide connections and routing for power or signals to transistors or other structures in areas above the transistors. For example, the connections and routing for power or signals may be provided in topside layers of the device. As used herein, the term “topside” refers to areas in a device that are vertically above an active layer of the device (e.g., above a transistor region of the device when viewed in a typical cross-sectional view). For example, topside may refer to components such as contacts or layers that are above a transistor region in a vertical dimension, as depicted in the figures and described herein. In some instances, the term “frontside” may be used interchangeably with the term “topside”.

As used herein, the term “routing” refers to any combination of metal vias, metal wires, metal traces, etc. that provide a path/route between two structures. Additional embodiments may be contemplated where the metal in “routing” is replaced with an alternative conductive material. For instance, the metal in “routing” may be replaced with a superconductor material, a semiconductor material, or a non-metal conductor.

Placing memory circuits in transistor regions of integrated circuit devices in large scale integrations may cause electrical (e.g., high resistance) and mechanical (e.g., footprint/area utilization and path blockage) issues. The present disclosure recognizes that these issues may be alleviated by placing memory circuits in locations between topside routing layers (e.g., topside metal routing layers) instead of in the transistor regions of the integrated circuit devices. Placing the memory circuits in these locations allows connections between the memory circuits and their associated signal routes (e.g., wordline and bitline routes) and power routes (e.g., power supply and ground supply routes) to be made over small distances. For example, the memory circuits may be coupled to signal and power routes in topside metal layers directly above or below the memory circuits. These shorter connection distances reduce resistances in the connections between the memory circuits and signal/power routes, which improves electrical properties for the operation of the memory circuits.

In various embodiments, having memory circuits out of the transistor regions of the devices by placing the memory circuits in between topside metal layers opens up footprint in the transistor regions. The opened up footprint may be utilized, for example, to increase the number of other types of transistors or circuit elements, allowing for more complex or powerful devices. Additionally, moving the memory circuits out of the transistor regions of the devices eliminates potential blockages by the memory circuits. Opening up the footprint and removing blockages may allow more flexibility in the design or manufacturing of integrated circuit devices. For instance, the design of integrated circuits may include more optimized routing strategies for signals in the devices with the opening up of the footprint and removal of blockages. Manufacturing may also be more efficient in certain instances with optimized design strategies.

Certain embodiments disclosed herein have three broad elements: 1) a transistor region; 2) first and second metal layers in topside metal layers above the transistor region where the first metal layer includes power supply routing, ground supply routing, and wordline routing and the second metal layer includes bitline routing, and 3) a memory circuit positioned between the first and second metal layers. In certain embodiments, the routing in the first metal layer is orthogonal to the routing in the second metal layer. The first metal layer may be above or below the memory circuit with the second metal layer being the corresponding layer below or above the memory circuit. In various embodiments, the memory circuit includes a plurality of active regions with at least one of a first type (e.g., n-type) and at least one of a second type (e.g., p-type), a plurality of transistors having gates and source/drain regions, and a plurality of vias that provide coupling between the components of the transistors and the routings in the first and second metal layers. In some contemplated embodiments, the memory circuit is a 6T SRAM memory cell where the memory circuit includes four (4) n-type transistors and two (2) p-type transistors.

Various illustrations of embodiments with these broad elements are now described in the present disclosure. It should be noted that the illustrated embodiments of the present disclosure depict design templates for devices with memory circuits positioned in between topside metal layers. These design templates provide basic building blocks from which many different types of routing schemes for devices may be constructed based on connection schemes to the memory circuit transistors in the design templates.

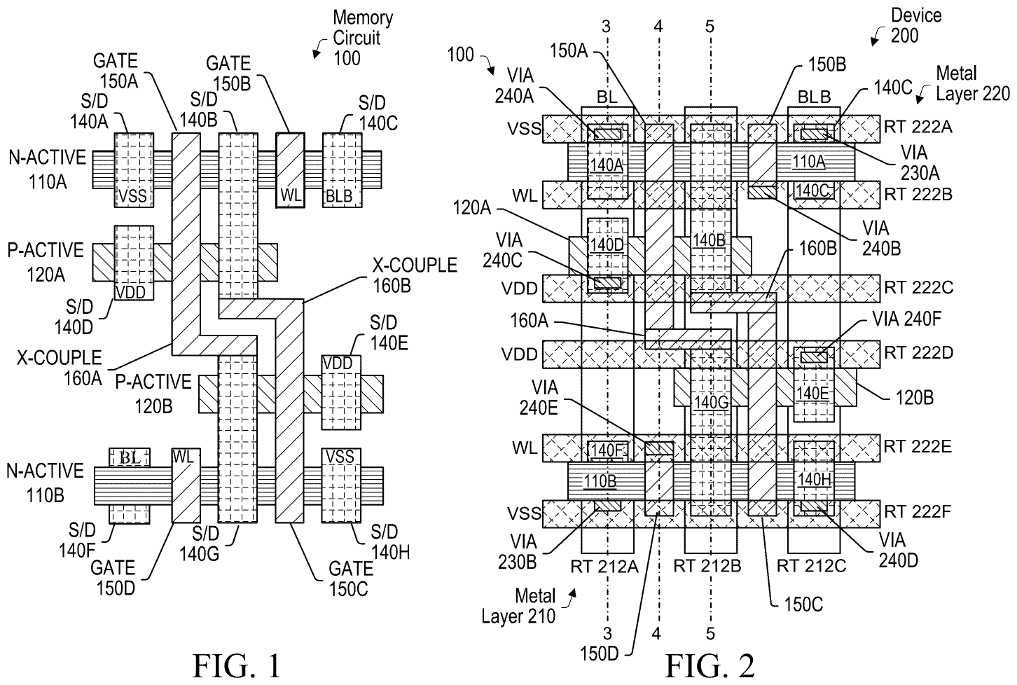

FIG. 1 depicts a top view representation of a memory circuit that can be located in topside metal layers, according to some embodiments. In the illustrated embodiment, memory circuit 100 is shown in isolation (e.g., without any metal layer routing above or below the memory circuit) for simplicity in describing the memory circuit. In various embodiments, memory circuit 100 includes two n-type active regions 110A, 110B (e.g., n-type active regions) and two p-type active regions 120A, 120B (e.g., p-type active regions). With the four active regions (and two of each type of active region), memory circuit 100 then includes various source/drain regions 140 and gates 150 to form a six-transistor (6T) memory circuit such as a 6T SRAM circuit.

In certain embodiments, active regions 110 and 120 of memory circuit 100 are active regions made of thin channel materials. For example, the channel materials may be on the order of two or fewer atomic layers. Thin channel materials may include materials such as, but not limited to, 2D (two-dimensional) materials, CNTs (carbon nano-tubes), and oxide semiconductors. Examples of 2D materials include, but are not limited to, graphene, silicene, BNNS (boron nitride nanosheets), TMDCs (transition-metal dichalcogenides), phosphorene, and metal oxide nanosheets. Utilizing these types of materials may allow similar active region characteristics to silicon to be achieved in a few layers that can be positioned between existing topside metal layers in a device layout. Memory circuits with these types of active regions and positioned between topside metal layers, as described herein, may be implemented in various designs of devices with the memory circuits placed at various locations in devices (such as device 200) to provide memory operations at various positions across the devices.

In the illustrated embodiment of FIG. 1, memory circuit 100 includes source/drain region 140A, source/drain region 140B, and source/drain region 140C formed over n-type active region 110A. Memory circuit 100 further includes source/drain region 140F formed under n-type active region 110B and source/drain region 140G and source/drain region 140H formed over n-type active region 110B. In various embodiments, source/drain region 140B is formed to extend over p-type active region 120A and source/drain region 140G is formed to extend over p-type active region 120B. Source/drain region 140D is also formed over p-type active region 120A and source/drain region 140E is formed over p-type active region 120B.

In certain embodiments, gate 150A is formed with gate material that extends over both n-type active region 110A and p-type active region 120A, thereby forming a transistor over each active region with the transistors being interconnected by the gate material. Similarly, gate 150C is formed with gate material that extends over both n-type active region 110B and p-type active region 120B to form interconnected transistors over each active region. Additional transistors are formed by gate 150B formed with gate material over n-type active region 110A and gate 150D formed with gate material over n-type active region 110B. Accordingly, memory circuit includes six (6) total transistors formed by the gate material of gates 150A-D.

In various embodiments, gate 150A is cross-coupled to source/drain region 140G by x-couple 160A and gate 150C is cross-coupled to source/drain region 140B by x-couple 160B. Cross-coupling of the gates to the source/drain regions forms the connections needed in the 6T SRAM circuit. Additionally, the illustrated embodiments of the present disclosure include identifiers for where various connections to routing above/below memory circuit 100 are to be placed. The identifiers are—VSS (connection for ground supply routing), VDD (connection for power supply routing), WL (connection for wordline routing), BL (connection for bitline routing), and BLB (connection for bitline routing complementary to BL). In the illustrated embodiment of FIG. 1, VSS connections are made to source/drain region 140A and source/drain region 140H, VDD connections are made to source/drain region 140D and source/drain region 140E, WL connections are made to gate 150B and gate 150D, a BL connection is made to source/drain region 140F, and a BLB connection is made to source/drain region 140C. Making these connections, along with x-couple 160A and x-couple 160B and the layout of gates and source/drain regions over the active regions, provides interconnections between the various gates and source/drain regions in order to allow memory circuit 100 to operate as a multi-transistor (e.g., six transistor) memory circuit.

FIG. 2 depicts a top view representation of a contemplated device with the memory circuit of FIG. 1 positioned vertically between two topside metal layers, according to some embodiments. In the illustrated embodiment, device 200 includes the components of memory circuit 100 positioned between two topside metal layers 210 and 220 of the device. For instance, device 200 includes memory circuit 100 positioned in the space vertically between metal layer 210 and metal layer 220. Metal layers 210 and 220 may be, for example, topside BEOL metal layers vertically above a transistor region and a substrate of device 200. In certain embodiments, metal layer 210 is the topside metal layer that is vertically closer to the transistor region of device 200 and metal layer 220 is the topside metal layer that is vertically further from the transistor region. Accordingly, with memory circuit 100 positioned between metal layers 210 and 220, metal layer 210 is a “bottom” metal layer and metal layer 220 is a “top” metal layer relative to the memory circuit 100 above a substrate (such as shown in FIGS. 2-5). Embodiments may be contemplated, however, where the bottom and top metal layers are reversed—e.g., metal layer 210 is the top metal layer above memory circuit 100 and metal layer 220 is the bottom metal layer below the memory circuit.

In various embodiments, metal layer 210 includes routings (“RT”) 212A-C and metal layer 220 includes routings (“RT”) 222A-F. As metal layer 210 and metal layer 220 are neighboring metal layers in the topside metal layers, routings 212A-C and routings 222A-F may run perpendicular (e.g., orthogonal) to each other, as shown in FIG. 2. Routings 212A-C and routings 222A-F may include signal routing (e.g., bitline or wordline routing), power supply routing, ground supply routing, or other routings. In certain embodiments, one or more of the routings 212 and routings 222 are global routings. Global routings may be, for example, routes that carry signals over long distances and try to avoid diversions in their pathways when passing above transistor regions to which they are not connected.

In certain embodiments, as shown in FIG. 2, routing 212A and routing 212C are bitline routings (e.g., complementary bitline routings “BL” and “BLB”). Routing 212B may, in some embodiments, be a global route passing by device 200. In the illustrated embodiment, routing 222A and routing 222F are ground supply (“VSS”) routing, routing 222C and 222D are power supply (“VDD”) routing, and routing 222B and 222E are wordline (“WL”) routing.

With memory circuit 100 positioned in between metal layer 210 and metal layer 220 in device 200, various connections may be made between the components of the memory circuit to the routings in the metal layers to connect the memory circuit for operation as a multi-transistor (e.g., six transistor) memory circuit. For instance, in certain embodiments, device 200 includes vias 230 for connecting components to metal layer 210 and vias 240 for connecting components to metal layer 220. In the illustrated embodiment of FIG. 2, for metal layer 210, a BL connection is made by via 230B connecting source/drain region 140F to routing 212A and a BLB connection is made by via 230A connecting source/drain region 140C to routing 212C. For metal layer 220, via 240A provides a connection between source/drain region 140A and routing 222A for one VSS (ground supply) connection. Via 240D then provides a connection between source/drain region 140H and routing 222F for another VSS connection. VDD connections are made by via 240C connecting source/drain region 140D to routing 222C and via 240F connecting source/drain region 140E to routing 222D. WL connections are made by via 240B connecting gate 150B to routing 222B and via 240E connecting gate 150D to routing 222E.

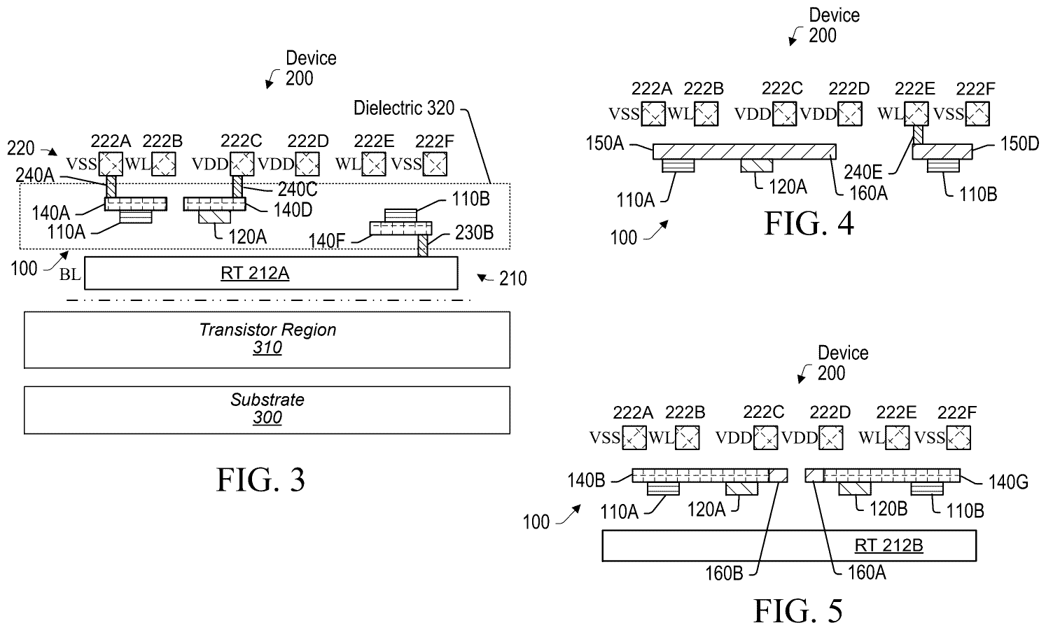

FIG. 3 is a cross-sectional side-view representation of device 200 showing memory circuit 100 along line 3-3 in FIG. 2, according to some embodiments. Note that some elements in device 200 (such as, but not limited to, substrate 300, transistor region 310, and dielectric 320) are shown representatively for illustrative purposes and that their dimensions and spacing relative to each other may vary. Additionally, for convenience in the drawings, substrate 300, transistor region 310, and dielectric 320 are shown only in FIG. 3 with the understanding that these elements of device 200 translate to the embodiments of the additional figures.

In various embodiments, metal layer 210 and metal layer 220 (e.g., the topside/BEOL metal layers) are positioned above transistor region 310. In certain embodiments, metal layer 210 and metal layer 220 are higher metal layers. For instance, metal layer 210 and metal layer 220 may be metal layers that are vertically further away from transistor region 310 than other metal layers (e.g., there are additional metal layers between transistor region 310 and metal layer 210). Metal layer 210 and metal layer 220 may, however, be any pair of adjacent (e.g., vertically neighboring) metal layers positioned above transistor region 310. For instance, embodiments may be contemplated where metal layer 210 and metal layer 220 are the two metal layers vertically closest to transistor region 310.

In certain embodiments, a layer of dielectric 320 is positioned between metal layer 210 and metal layer 220. Dielectric 320 may include any suitable dielectric material for providing electrical insulation and mechanical support between metal layer 210 and metal layer 220. For instance, dielectric 320 may include silicon oxide. Memory circuit 100, including active regions 110/120, may be formed between metal layer 210 and metal layer 220 and surrounded, at least partially, by dielectric 320. In various embodiments, as shown in FIG. 3, active regions 110A, 110B, 120A and routings 222A-F are in parallel and extend into/out of the page while source/drain regions 140A, 140D, 140F and routing 212A run horizontally along the page.

In the illustrated embodiment of FIG. 3, via 240A is shown connecting source/drain region 140A (positioned over and connecting to active region 110A) to routing 222A for a VSS connection and via 240C is shown connecting source/drain region 140D (positioned over and connecting to active region 120A) to routing 222C for a VDD connection. Along the same cross-section, via 230B connects source/drain region 140F (positioned under and connecting to active region 110B) to routing 212A for a bitline (“BL”) connection. As shown in FIG. 3, vias 230 and vias 240 may provide connection from inside dielectric 320, where the components of memory circuit 100 are located, to outside the dielectric where the metal layer routings are located.

FIG. 4 is a cross-sectional side-view representation of device 200 showing memory circuit 100 along line 4-4 in FIG. 2, according to some embodiments. In the illustrated embodiment, via 240E is shown connecting gate 150D (positioned over and connecting to active region 110B) to routing 222E for a wordline (“WL”) connection. Meanwhile, gate 150A is shown to be positioned over and connecting between active region 110A and active region 120A. The end of gate 150A also includes x-couple 160A, described herein.

FIG. 5 is a cross-sectional side-view representation of device 200 showing memory circuit 100 along line 5-5 in FIG. 2, according to some embodiments. Along the cross-section of FIG. 5, there are no via connections to metal layer 210 or metal layer 220. In the illustrated embodiment, source/drain region 140B is shown to be positioned over and connecting between active region 110A and active region 120A with x-couple 160B connected to the end of the source/drain region. Similarly, source/drain region 140G is shown to be positioned over and connecting between active region 110B and active region 120B with x-couple 160A connected to the end of the source/drain region.

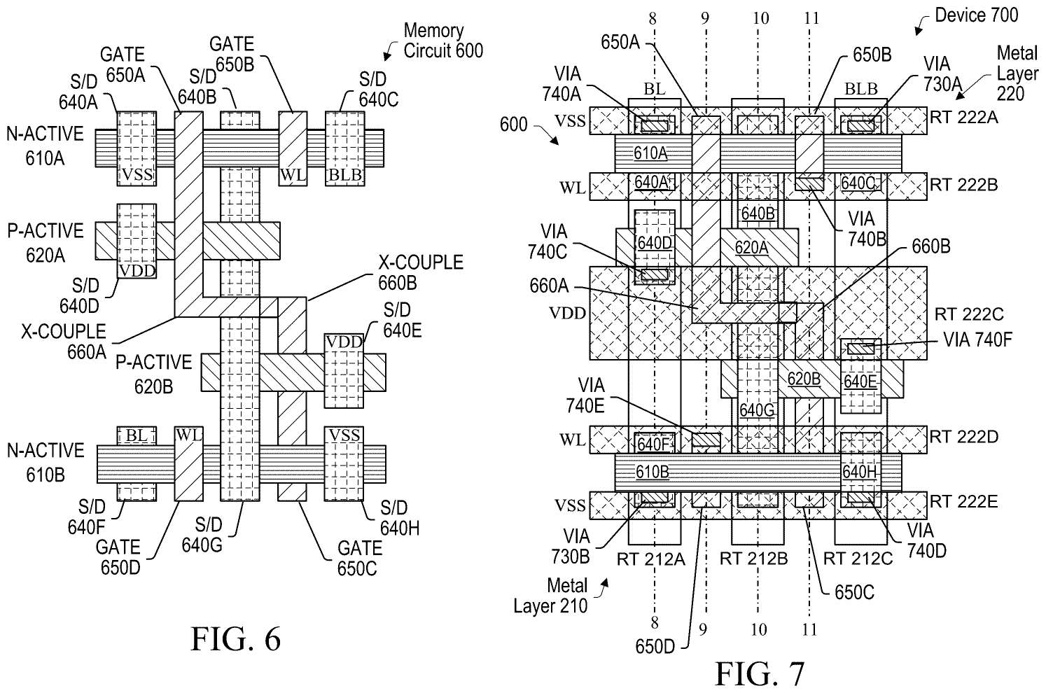

In some embodiments, the cross-coupling between source/drain regions in a memory circuit is implemented on two opposing sides of the transistor layers. For instance, the cross-coupling may be implemented using sides both above and below the transistor layers of active regions and source/drain regions in the memory circuit. Using cross-coupling on two opposing sides may reduce the area of the memory circuit. FIGS. 6-11 depict representations of a contemplated embodiment of such a memory circuit positioned between BEOL/topside metal layers.

FIG. 6 depicts a top view representation of memory circuit 600 that can be located in topside metal layers, according to some embodiments. In the illustrated embodiment, memory circuit 600 is shown in isolation (e.g., without any metal layer routing above or below the memory circuit) for simplicity in describing the memory circuit. In various embodiments, memory circuit 600, similar to memory circuit 100, includes two n-type active regions 610A, 610B (e.g., n-type active regions) and two p-type active regions 620A, 620B (e.g., p-type active regions). With the four active regions (and two of each type of active region), memory circuit 600 then includes various source/drain regions 640 and gates 650 to form a six-transistor (6T) memory circuit such as a 6T SRAM circuit.

In the illustrated embodiment of FIG. 6, memory circuit 600 includes source/drain region 640A and source/drain region 640C formed over n-type active region 610A while source/drain region 640B is formed under n-type active region 610A. Memory circuit 600 further includes source/drain region 640F formed under n-type active region 610B with source/drain region 640G and source/drain region 640H formed over n-type active region 610B. In various embodiments, source/drain region 640B is formed to extend under p-type active region 620A and source/drain region 640G is formed to extend over p-type active region 620B. Note that source/drain region 640B may be positioned vertically below the active regions while source/drain region 640G is positioned vertically above the active regions (shown in more detail in FIG. 10). Source/drain region 640D is also formed over p-type active region 620A and source/drain region 640E is formed over p-type active region 620B.

In certain embodiments, gate 650A is formed with gate material that extends over both n-type active region 610A and p-type active region 620A, thereby forming a transistor over each active region with the transistors being interconnected by the gate material. Gate 650C is formed with gate material that extends under both n-type active region 610B and p-type active region 620B to form interconnected transistors under each active region. Additional transistors are formed by gate 650B formed with gate material over n-type active region 610A and gate 650D formed with gate material over n-type active region 610B. Accordingly, memory circuit includes six (6) total transistors formed by the gate material of gates 650A-D.

In various embodiments, gate 650A is cross-coupled to source/drain region 640G by x-couple 660A and gate 650C is cross-coupled to source/drain region 640B by x-couple 660B. The cross-couplings are also shown by cross-section in FIGS. 9-11, described below. Cross-coupling of the gates to the source/drain regions forms the connections needed in the 6T SRAM circuit. In the illustrated embodiment of FIG. 6, VSS connections are made to source/drain region 640A and source/drain region 640H, VDD connections are made to source/drain region 640D and source/drain region 640E, WL connections are made to gate 650B and gate 650D, a BL connection is made to source/drain region 640F, and a BLB connection is made to source/drain region 640C. Making these connections, along with x-couple 660A and x-couple 660B and the layout of gates and source/drain regions over/under the active regions, provides interconnections between the various gates and source/drain regions in order to allow memory circuit 600 to operate as a multi-transistor (e.g., six transistor) memory circuit.

FIG. 7 depicts a top view representation of a contemplated device with the memory circuit of FIG. 6 positioned vertically between two topside metal layers, according to some embodiments. In the illustrated embodiment, device 700 includes the components of memory circuit 600 positioned between two topside metal layers 210 and 220 of the device. For instance, device 700 includes memory circuit 600 positioned in the space vertically between metal layer 210 and metal layer 220. Metal layers 210 and 220 may be, for example, topside BEOL metal layers vertically above a transistor region and a substrate of device 700, as described herein.

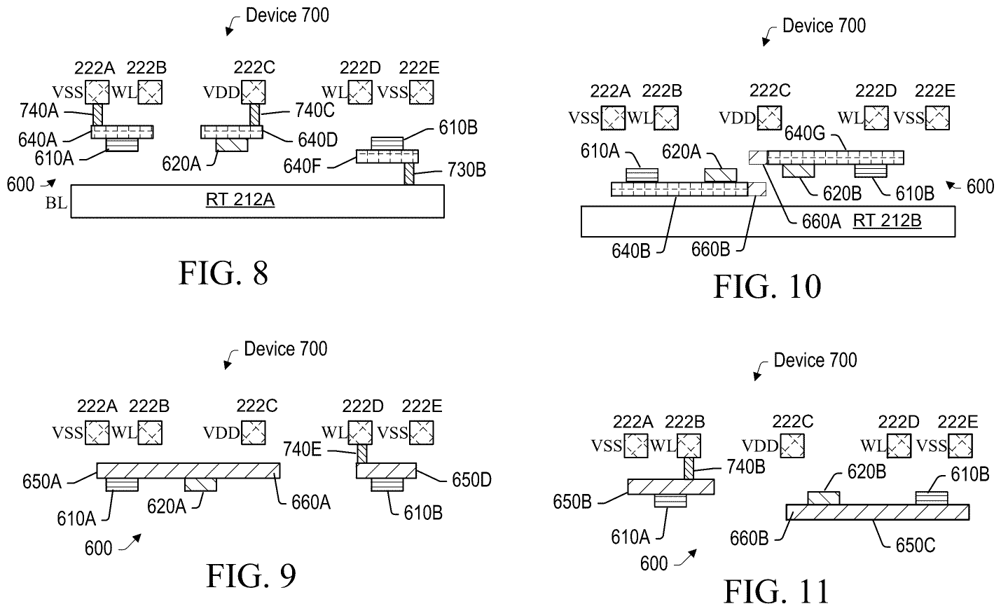

FIGS. 8-11 are cross-sectional side-view representations of device 700 showing the various connections from metal layers to memory circuit 600 using vias 730 and vias 740. FIGS. 8-11 also show the placement of gates and source/drain regions either above or below active regions, as described herein. FIG. 8 is a cross-sectional side-view representation of device 700 showing memory circuit 600 along line 8-8 in FIG. 7, according to some embodiments. Note that some elements in device 700 (such as, but not limited to, a substrate, a transistor region, and a dielectric) are not shown for convenience but are previously described above with respect to FIG. 3.

In the illustrated embodiment of FIG. 8, via 740A is shown connecting source/drain region 640A (positioned over and connecting to active region 610A) to routing 222A for a VSS connection and via 740C is shown connecting source/drain region 640D (positioned over and connecting to active region 620A) to routing 222C for a VDD connection. Along the same cross-section, via 730B connects source/drain region 640F (positioned under and connecting to active region 610B) to routing 212A for a bitline (“BL”) connection.

FIG. 9 is a cross-sectional side-view representation of device 700 showing memory circuit 600 along line 9-9 in FIG. 7, according to some embodiments. In the illustrated embodiment, via 740E is shown connecting gate 650D (positioned over and connecting to active region 610B) to routing 222D for a wordline (“WL”) connection. Meanwhile, gate 650A is shown to be positioned over and connecting between active region 610A and active region 620A. The end of gate 650A also includes x-couple 660A, described herein.

FIG. 10 is a cross-sectional side-view representation of device 700 showing memory circuit 600 along line 10-10 in FIG. 7, according to some embodiments. Along the cross-section of FIG. 10, there are no via connections to metal layer 210 or metal layer 220. In the illustrated embodiment, source/drain region 640B is shown to be positioned under and connecting between active region 610A and active region 620A with x-couple 660B connected to the end of the source/drain region. Source/drain region 640G is shown to be positioned over and connecting between active region 610B and active region 620B with x-couple 660A connected to the end of the source/drain region.

FIG. 11 is a cross-sectional side-view representation of device 700 showing memory circuit 600 along line 11-11 in FIG. 7, according to some embodiments. In the illustrated embodiment, via 740B is shown connecting gate 650B (positioned over and connecting to active region 610A) to routing 222B for a wordline (“WL”) connection. Meanwhile, gate 650C is shown to be positioned under and connecting between active region 610B and active region 620B. The end of gate 650C also includes x-couple 660B, described herein.

In certain embodiments, as shown by the combination of FIGS. 7-11, routing 212A and routing 212C are bitline routings (e.g., complementary bitline routings “BL” and “BLB”). Routing 212B may, in some embodiments, be a global route passing by device 200. In the illustrated embodiment, routing 222A and routing 222E are ground supply (“VSS”) routing, routing 222C is power supply (“VDD”) routing, and routing 222B and 222D are wordline (“WL”) routing. Note that with reduced space of memory circuit 600 in comparison to memory circuit 100 that routing 222C may be a single combined “double width” route for connecting to memory circuit 600 whereas memory circuit 100 had two separate VDD routings that were connected to by vias. The single VDD routing path 222C may be more efficient in power transfer to the memory circuit.

With memory circuit 600 positioned in between metal layer 210 and metal layer 220 in device 700, various connections may be made between the components of the memory circuit to the routings in the metal layers to connect the memory circuit for operation as a multi-transistor (e.g., six transistor) memory circuit. For instance, in certain embodiments, device 700 includes vias 730 for connecting components to metal layer 210 and vias 740 for connecting components to metal layer 220. In the illustrated embodiments of FIGS. 7-11, for metal layer 210, a BL connection is made by via 730B connecting source/drain region 640F to routing 212A and a BLB connection is made by via 730A connecting source/drain region 640C to routing 212C. For metal layer 220, via 740A provides a connection between source/drain region 640A and routing 222A for one VSS (ground supply) connection. Via 740D then provides a connection between source/drain region 640H and routing 222F for another VSS connection. VDD connections are made by via 740C connecting source/drain region 640D to routing 222C and via 740F connecting source/drain region 640E to routing 222D. WL connections are made by via 740B connecting gate 650B to routing 222B and via 740E connecting gate 650D to routing 222E.

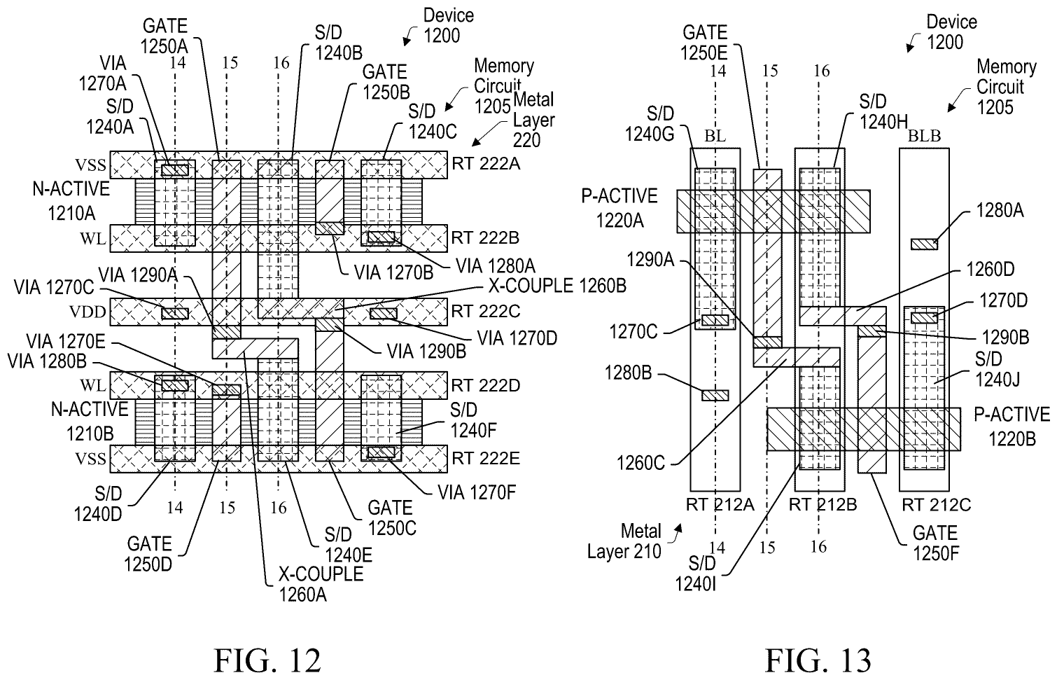

With the utilization of thin channel materials for the active regions, various embodiments may also be contemplated where n-type active regions and p-type active regions are stacked vertically between metal layers. FIGS. 12-16 depict representations of a contemplated embodiment of a memory circuit with vertically stacked active regions positioned between BEOL/topside metal layers. FIG. 12 depicts a top view representation of a contemplated device with a memory circuit having stacked active regions positioned vertically between two topside metal layers, according to some embodiments. FIG. 13 depicts a bottom view representation of the contemplated device with the memory circuit of FIG. 12, according to some embodiments. In the illustrated embodiments, device 1200 includes memory circuit 1205 positioned between bottom metal layer 210 (shown in FIG. 13) and top metal layer 220 (shown in FIG. 12). Note that only top metal layer 220 and n-type active regions 1210 are shown by illustration in FIG. 12 and that bottom metal layer 210 and p-type active regions 1220 are only shown by illustration in FIG. 13 for simplicity in the drawings.

In various embodiments, memory circuit 1205 includes two n-type active regions 1210A, 1210B (e.g., n-type active regions)(shown in FIG. 12) and two p-type active regions 1220A, 1220B (e.g., p-type active regions)(shown in FIG. 13). With the four active regions (and two of each type of active region), memory circuit 1205 then includes various source/drain regions 1240 and gates 1250 to form a six-transistor (6T) memory circuit such as a 6T SRAM circuit.

As shown in FIG. 12, memory circuit 1205 includes source/drain region 1240A, source/drain region 1240B, and source/drain region 1240C formed over n-type active region 1210A. Memory circuit 1205 further includes source/drain region 1240D, source/drain region 1240E, and source/drain region 1240F formed over n-type active region 1210B. In certain embodiments, gate 1250A is formed by gate material over n-type active region 1210A with the gate material extending into the space between the active regions. Similarly, gate 1250C is formed by gate material over n-type active region 1210B with the gate material extending into the space between the active regions. Additional transistors are formed by gate 1250B formed with gate material over n-type active region 1210A and gate 1250D formed with gate material over n-type active region 1210B.

As shown in FIG. 13, memory circuit 1205 further includes source/drain region 1240G and source/drain region 1240H formed over p-type active region 1220A and source/drain region 1240I and source/drain region 1240J formed over p-type active region 1220B. Gate 1250E is formed by gate material over p-type active region 1220A with the gate material extending into the space between the active regions. Gate 1250F is formed by gate material over p-type active region 1220B with the gate material extending into the space between the active regions. Accordingly, memory circuit 1205 includes six (6) total transistors formed by the gate material of gates 1250A-F.

In the illustrated embodiments of FIGS. 12 and 13, VSS connections are made to source/drain region 1240A and source/drain region 1240F by via 1270A and via 1270F from routing 222A and routing 222E, respectively. WL connections are made to gate 1250B and gate 1250D by via 1270B and via 1270E from routing 222B and routing 222D, respectively. A BL connection is made to source/drain region 1240D by via 1280B from routing 212A and a BLB connection is made to source/drain region 1240C by via 1280A from routing 212C. VDD connections are made to source/drain region 1240G and source/drain region 1240J by via 1270C and via 1270D, respectively, from routing 222C.

In certain embodiments, gate 1250A is coupled to gate 1250E by via 1290A. Additionally, gate 1250A is cross-coupled to source/drain region 1240E by x-couple 1260A and gate 1250E is cross-coupled to source/drain region 1240I by x-couple 1260C. Via 1290A and the cross-couplings are also shown by cross-section in FIGS. 15-16, described below. In a similar manner, gate 1250C is coupled to gate 1250F by via 1290B with gate 1250C cross-coupled to source/drain region 1240B by x-couple 1260B and gate 1250F cross-coupled to source/drain region 1240H by x-couple 1260D. Making all the various connections of the gates and source/drain regions described above, along with the cross-couplings the gates to the source/drain regions, forms the connections needed for memory circuit 1205 to be connected and operate as a multi-transistor (e.g., six transistor) memory circuit.

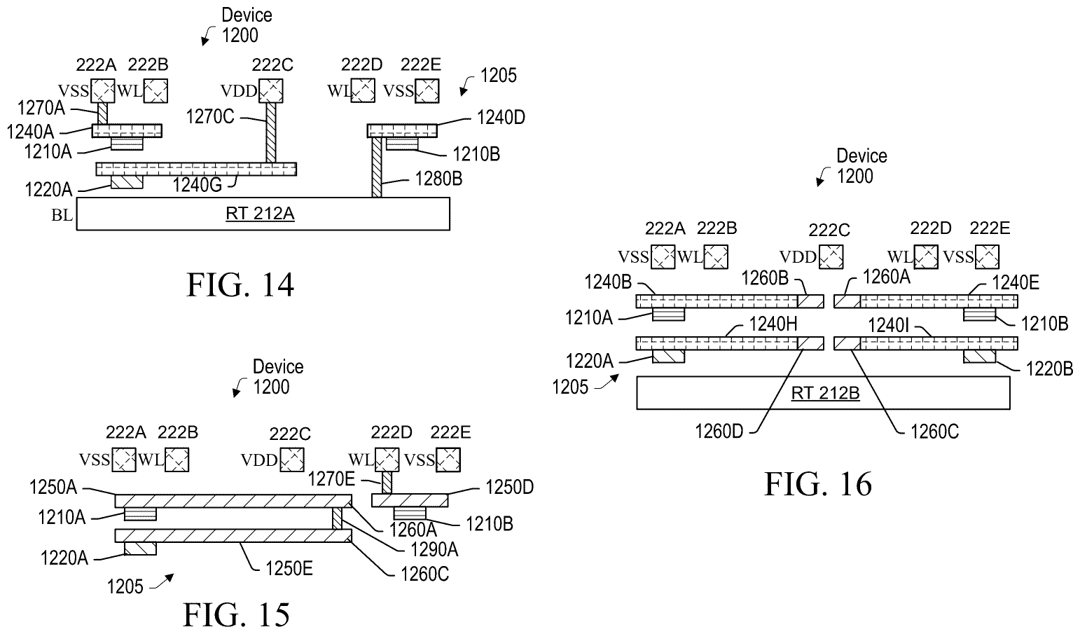

FIGS. 14-16 are cross-sectional side-view representations of device 1200 showing the various connections from metal layers to memory circuit 1205 using vias 1270, 1280, 1290. FIGS. 14-16 also show the vertical stacking of n-type active regions above p-type active regions, as described herein. It should be understood that additional embodiments may be contemplated where the p-type active regions are stacked above the n-type active regions as well as various placements of gates and source/drain regions relative to the active regions.

FIG. 14 is a cross-sectional side-view representation of device 1200 showing memory circuit 1205 along line 14-14 in FIGS. 12 and 13, according to some embodiments. Note that some elements in device 1200 (such as, but not limited to, a substrate, a transistor region, and a dielectric) are not shown for convenience in the drawings but are previously described above with respect to FIG. 3.

In the illustrated embodiment of FIG. 14, via 1270A is shown connecting source/drain region 1240A (positioned over and connecting to active region 1210A) to routing 222A for a VSS connection and via 1270C is shown connecting source/drain region 1240G (positioned over and connecting to active region 1220A) to routing 222C for a VDD connection. Along the same cross-section, via 1280B connects source/drain region 1240D (positioned over and connecting to active region 1210B) to routing 212A for a bitline (“BL”) connection.

FIG. 15 is a cross-sectional side-view representation of device 1200 showing memory circuit 1205 along line 15-15 in FIGS. 12 and 13, according to some embodiments. In the illustrated embodiment, via 1270E is shown connecting gate 1250D (positioned over and connecting to active region 1210B) to routing 222D for a wordline (“WL”) connection. Gate 1250A is shown to be positioned over and connecting to active region 1210A and gate 1250E is shown to be positioned over and connecting to active region 1220A. Gate 1250A and gate 1250E extend to allow connection between the gates by via 1290A. The end of gate 1250A also includes x-couple 1260A and the end of gate 150E includes x-couple 1260C, described above.

FIG. 16 is a cross-sectional side-view representation of device 1200 showing memory circuit 1205 along line 16-16 in FIGS. 12 and 13, according to some embodiments. Along the cross-section of FIG. 16, there are no via connections to metal layer 210 or metal layer 220. In the illustrated embodiment, source/drain region 1240B is shown to be positioned over and connecting to active region 1210A and source/drain region 1240H is shown to be positioned over and connecting to active region 1220A. Source/drain region 1240B also includes x-couple 1260B connected to the end of the source/drain region while source/drain region 1240H includes x-couple 1260D connected to the end of the source/drain region. Source/drain region 1240E is shown to be positioned over and connecting to active region 1210B and source/drain region 1240I is positioned over and connected to active region 1220B. Source/drain region 1240E has x-couple 1260A connected to its end and source/drain region 1240I has x-couple 1260C connected to its end.

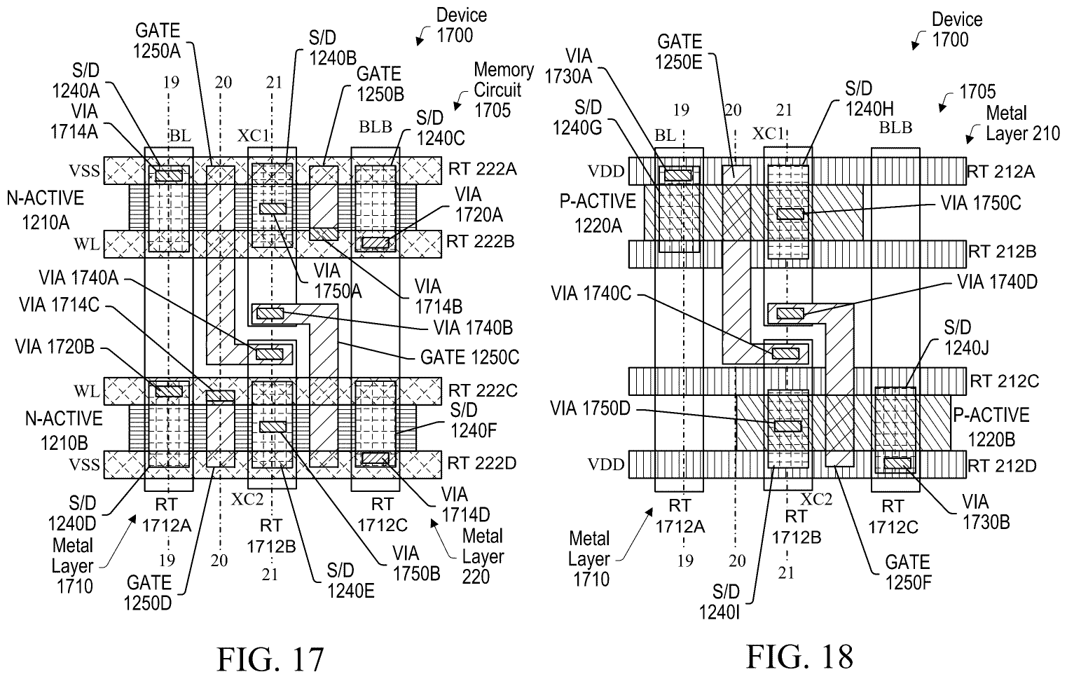

Another possible utilization of thin channel materials for the active regions in various embodiments includes implementation of a third (middle) metal layer between vertically stacked active regions and between a first (top) and a second (bottom) metal layers. With the implementation of the third (middle) metal layer, the top and bottom metal layers have parallel routing paths while the middle metal layer has routing that is perpendicular (e.g., orthogonal) to the other routings. In certain embodiments, the middle metal layer may be utilized for providing cross-coupling connections between gates and source/drain regions as well as connections to routing for bitlines. With the additional middle metal layer, routings for power supply (VDD) may be moved to the bottom metal layer. Having the additional metal layer allows for additional redundancy in power/ground supply connections and routing. FIGS. 17-21 depict representations of a contemplated embodiment of a memory circuit with vertically stacked active regions positioned between BEOL/topside metal layers.

FIG. 17 depicts a top view representation of a contemplated device with a memory circuit having stacked active regions positioned vertically between two topside metal layers and with a topside middle metal layer vertically between the active regions, according to some embodiments. FIG. 18 depicts a bottom view representation of the contemplated device with the memory circuit of FIG. 17, according to some embodiments. In the illustrated embodiments, device 1200 includes memory circuit 1205 positioned between top metal layer 220 (shown in FIG. 17) and bottom metal layer 210 (shown in FIG. 18). Middle metal layer 1710 is positioned between the active regions and between top metal layer 220 and bottom metal layer 210. Note that only top metal layer 220 and n-type active regions 1210 are shown by illustration in FIG. 17 and only bottom metal layer 210 and p-type active regions 1220 are shown by illustration in FIG. 18 for simplicity in the drawings while middle metal layer 1710 is shown in both FIGS. 17 and 18.

With the addition of middle metal layer 1710 to device 1700, the routings for signals, power supply, and ground supply may be divided between three metal layers of routing. In certain embodiments, top metal layer 220 includes routing 222A and routing 222D for VSS (ground supplying routing) along with routing 222B and routing 222C for wordline (WL) routing. Power supply (VDD) routing is provided by routing 212A and routing 212D in bottom metal layer 210. Bottom metal layer 210 may also include routing 212B and routing 212C, which may be some type of global routing or simply spacer routing between the power supply routings. Middle metal layer 1710 includes complementary bitline routings—routing 1712A (BL routing) and routing 1712C (BLB routing). Middle metal layer 1710 may also include routing 1712B, which may be used for cross-coupling (XC) connections between gates and source/drain regions. Note that routing 1712B may be divided into separated sections (“XC1” and “XC2”) to provide the different cross-coupling connections necessary (shown also by example in FIG. 21, described below).

In certain embodiments, memory circuit 1705 includes two n-type active regions 1210A, 1210B (e.g., n-type active regions)(shown in FIG. 17) and two p-type active regions 1220A, 1220B (e.g., p-type active regions)(shown in FIG. 18). With the four active regions (and two of each type of active region), memory circuit 1705 then includes various source/drain regions 1240 and gates 1250 to form a six-transistor (6T) memory circuit such as a 6T SRAM circuit.

For instance, as shown in FIG. 17, memory circuit 1705 includes source/drain region 1240A, source/drain region 1240B, and source/drain region 1240C formed over n-type active region 1210A. Memory circuit 1705 further includes source/drain region 1240D, source/drain region 1240E, and source/drain region 1240F formed over n-type active region 1210B. In certain embodiments, gate 1250A is formed by gate material over n-type active region 1210A with the gate material extending into the space between the active regions. Similarly, gate 1250C is formed by gate material over n-type active region 1210B with the gate material extending into the space between the active regions. Additional transistors are formed by gate 1250B formed with gate material over n-type active region 1210A and gate 1250D formed with gate material over n-type active region 1210B.

As shown in FIG. 18, memory circuit 1705 further includes source/drain region 1240G and source/drain region 1240H formed over p-type active region 1220A and source/drain region 1240I and source/drain region 1240J formed over p-type active region 1220B. Gate 1250E is formed by gate material over p-type active region 1220A with the gate material extending into the space between the active regions. Gate 1250F is formed by gate material over p-type active region 1220B with the gate material extending into the space between the active regions. Accordingly, memory circuit 1705 includes six (6) total transistors formed by the gate material of gates 1250A-F and is similar in structure to memory circuit 1205 (shown in FIGS. 12 and 13).

In the illustrated embodiments of FIGS. 17 and 18, VSS connections are made to source/drain region 1240A and source/drain region 1240F by via 1714A and via 1714D from routing 222A and routing 222D, respectively. WL connections are made to gate 1250B and gate 1250D by via 1714B and via 1714C from routing 222B and routing 222C, respectively. With BL and BLB routing being in middle metal layer 1710, a BL connection is made to source/drain region 1240D by via 1720B from routing 1712A and a BLB connection is made to source/drain region 1240C by via 1720A from routing 1712C. Finally, with VDD routing in bottom metal layer 210, a VDD connection is made to source/drain region 1240G by via 1730A from routing 212A and a VDD connection is made to source/drain region 1240J by via 1730B from routing 212D.

As described above, routing 1712B in middle metal layer 1710 is utilized to provide connections for cross-coupling in device 1700. For instance, in certain embodiments (as also seen in FIG. 21, described below), gate 1250A is coupled to XC2 routing section of routing 1712B by via 1740A and gate 1250E is coupled to XC2 routing section by via 1740C. Thus, XC2 routing section may connect gate 1250A to gate 1250E. Additionally, gate 1250A is cross-coupled to source/drain region 1240E through XC2 routing section and via 1750B and gate 1250E is cross-coupled to source/drain region 1240I through XC2 routing section and via 1750D. In a similar manner, gate 1250C is coupled to XC1 routing section of routing 1712B by via 1740B and gate 1250F is coupled to XC1 routing section by via 1740D. Thus, XC1 routing section may connect gate 1250C to gate 1250F. Additionally, gate 1250C is cross-coupled to source/drain region 1240B through XC1 routing section and via 1750A and gate 1250F is cross-coupled to source/drain region 1240H through XC1 routing section and via 1750C. Making all the various connections of the gates and source/drain regions described above, along with the cross-couplings the gates to the source/drain regions, forms the connections needed for memory circuit 1705 to be connected and operate as a multi-transistor (e.g., six transistor) memory circuit.

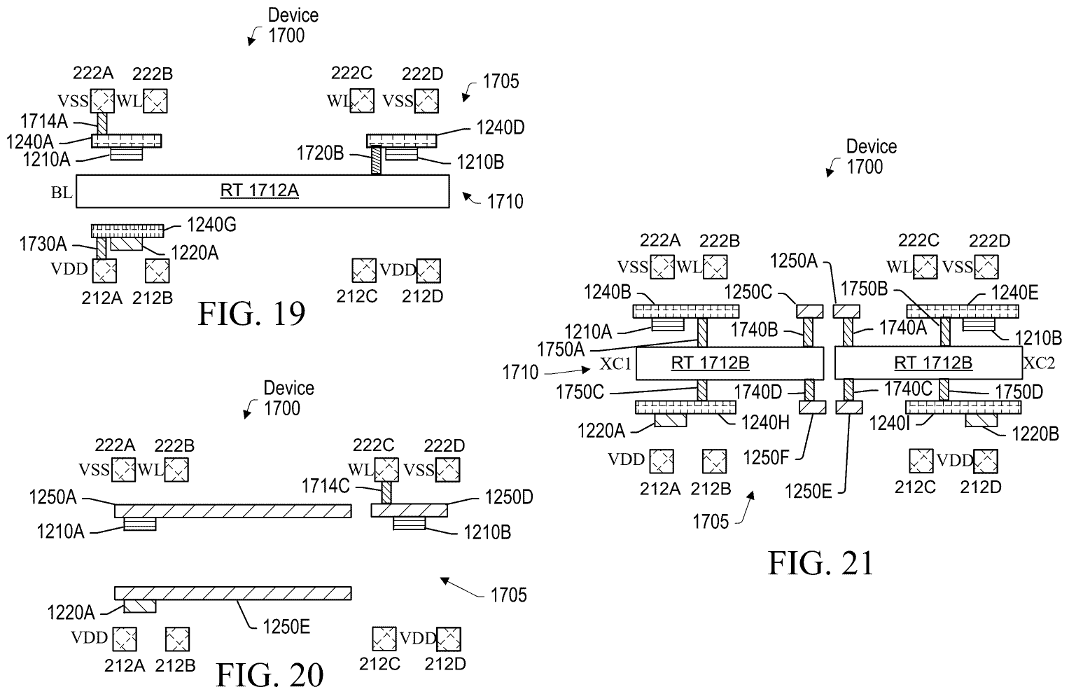

FIGS. 19-21 are cross-sectional side-view representations of device 1700 showing the various connections from metal layers to memory circuit 1705 using vias 1720, 1730, 1740, and 1750. FIGS. 19-21 also show the vertical stacking of n-type active regions above p-type active regions with middle metal layer 1710 and routings 1712 vertically between the active regions, as described herein. It should be understood that additional embodiments may be contemplated where the p-type active regions are stacked above the n-type active regions as well as various placements of gates and source/drain regions relative to the active regions.

FIG. 19 is a cross-sectional side-view representation of device 1700 showing memory circuit 1705 along line 19-19 in FIGS. 17 and 18, according to some embodiments. Note that some elements in device 1700 (such as, but not limited to, a substrate, a transistor region, and a dielectric) are not shown for convenience in the drawings but are previously described above with respect to FIG. 3.

In the illustrated embodiment of FIG. 19, via 1714A is shown connecting source/drain region 1240A (positioned over and connecting to active region 1210A) to routing 222A for a VSS connection and via 1730A is shown connecting source/drain region 1240G (positioned over and connecting to active region 1220A) to routing 212A for a VDD connection. Along the same cross-section, via 1720B connects source/drain region 1240D (positioned over and connecting to active region 1210B) to routing 1712A for a bitline (“BL”) connection.

FIG. 20 is a cross-sectional side-view representation of device 1700 showing memory circuit 1705 along line 20-20 in FIGS. 17 and 18, according to some embodiments. In the illustrated embodiment, via 1714C is shown connecting gate 1250D (positioned over and connecting to active region 1210B) to routing 222C for a wordline (“WL”) connection. Gate 1250A is shown to be positioned over and connecting to active region 1210A and active region 620A and gate 1250E is shown to be positioned over and connecting to active region 1220A. Gate 1250A and gate 1250E extend to allow connection between the gates through middle metal layer 1710 (which has no routing along the cross-section shown in FIG. 20). Thus, the end of gate 1250A and the end of gate 150E may include 1-shaped sections (which may be referred to as x-couples, in some embodiments) that allow for cross-coupling of the gates, as shown in FIG. 21.

FIG. 21 is a cross-sectional side-view representation of device 1700 showing memory circuit 1705 along line 21-21 in FIGS. 17 and 18, according to some embodiments. Along the cross-section of FIG. 17, there are no via connections to metal layer 210 or metal layer 220. In the illustrated embodiment, source/drain region 1240B is shown to be positioned over and connected to active region 1210A and source/drain region 1240H is shown to be positioned over and connected to active region 1220A. Source/drain region 1240B is coupled, by via 1750A, to cross-couple routing in XC1 section of routing 1712B with the cross-couple routing also connected to gate 1250C by via 1740B and gate 1250F by via 1740D. The cross-couple routing in XC1 section is further coupled to source/drain region 1240H by via 1750C, thereby cross-coupling gate 1250C, gate 1250F, source/drain region 1240B, and source/drain region 1240H.

Gate 1250A, gate 1250E, source/drain region 1240E, and source/drain region 1240I are cross-coupled in a similar manner. For instance, source/drain region 1240E is shown to be positioned over and connected to active region 1210B and source/drain region 1240I is shown to be positioned over and connected to active region 1220B. Source/drain region 1240E is coupled, by via 1750B, to cross-couple routing in XC2 section of routing 1712B with the cross-couple routing also connected to gate 1250A by via 1740A and gate 1250E by via 1740C. The cross-couple routing in XC2 section is further coupled to source/drain region 1240I by via 1750D to complete the cross-coupling connections.

The various embodiments of memory circuits described herein are memory circuits designed to be placed in between BEOL/topside metal layers through the implementation of thin channel materials for the active regions of the memory circuits. Forming memory circuits in between BEOL metal layers allows memory circuits to be positioned at a variety of locations along a device structure to allow greater circuit design flexibility. Additionally, memory circuits may be placed closed to related transistors to reduce signal latency between memory circuits and their related transistors.

### Example Manufacturing Method

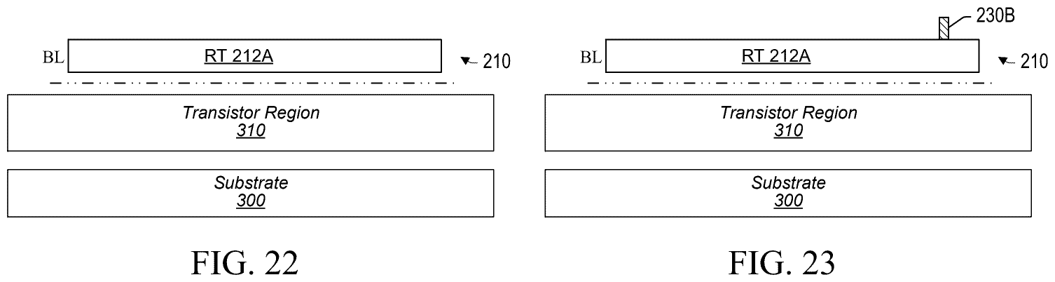

FIGS. 22-29 depict cross-sectional side-view representations of various possible steps in an exemplary embodiment of a method for manufacturing memory circuit 100 between two topside metal layers of device 200 (as shown in FIGS. 2-5). Note that FIGS. 22-29 are shown along the same cross-sectional view of FIG. 3 for showing results of manufacturing (e.g., process) steps to form memory circuit 100 in device 200. While the cross-sectional side-view representations in FIGS. 22-29 illustrate possible structural results of manufacturing steps for a memory circuit being formed between two topside metal layers (e.g., BEOL layers), it should be understood that similar manufacturing steps may be applied to the additional embodiments of devices described herein. Furthermore, it is noted that FIGS. 22-29 depict cross-sectional side-view representations of intermediate structural results (e.g., structural end results for layers in a layer-by-layer manufacturing process) of manufacturing steps involved in forming a memory circuit between topside metal layers.

In various embodiments, one or more semiconductor manufacturing processing steps are implemented to form the intermediate structural results or structural end results depicted in FIGS. 22-29. Examples of semiconductor manufacturing processing steps include, but are not limited to, wafer fabrication, etching (e.g., material removal), photolithography processing, deposition (e.g., material deposition), planarization (e.g., chemical mechanical planarization), ion implantation (e.g., doping), packaging, and packaging test (e.g., end product testing). Etching may include any of various etching techniques such as, but not limited to, wet etching, dry etching, plasma etching, and laser etching. Photolithography processing may include steps for mask deposition, irradiation (e.g., patterning), pattern transfer (including any related etching, deposition, or ion implantation steps), and mask removal (if necessary). Material deposition may include deposition processes such as, but not limited to, physical deposition, chemical deposition, chemical vapor deposition, evaporation, diffusion, spin coating, and electron beam deposition.

Any of the various semiconductor manufacturing processing steps mentioned above along with any related semiconductor manufacturing processing steps not explicitly disclosed may be implemented to arrive at the structures depicted in FIGS. 22-29 with the understanding that those skilled in the art would be able to determine a set of appropriate semiconductor manufacturing processing steps for implementing the depicted structures based on the present disclosure. Additionally, at some points throughout the present disclosure, semiconductor manufacturing processing steps may be explicitly recited in relation to specific structures. In such instances, it is understood that variations beyond the explicitly recited semiconductor manufacturing processing steps may be possible as known to those skilled in the art. Thus, while FIGS. 22-29 depict one exemplary embodiment for step-by-step manufacturing of devices described herein, additional embodiments for manufacturing devices described herein may be contemplated with modifications or alternatives that fall within the spirit or scope of the present disclosure where such modification or alternatives may include variations on the disclosed semiconductor manufacturing processing steps.

FIG. 22 is a cross-sectional side-view representation of a first manufacturing step of a memory circuit positioned between two topside metal layers, according to some embodiments. In the illustrated embodiment, topside metal layer 210 is formed above transistor region 310 and substrate 300. Topside metal layer 210, as described herein, may be a topside BEOL metal layer vertically above transistor region 310 and substrate 300. In various embodiments, additional topside metal layers are positioned between topside metal layer 210 and transistor region 310. For instance, topside metal layer 210 may be a metal layer that is vertically further away from transistor region 310 than other topside metal layers. Embodiments may be contemplated where topside metal layer 210 is the topside metal layer closest to transistor region 310.

As described herein, topside metal layer 210 may include various routings. In the illustrated embodiment, routing 212A (e.g., bitline “BL” routing) is shown along the cross-sectional side-view representation. Turning to FIG. 23, a cross-sectional side-view representation of a second manufacturing step of the memory circuit positioned between two topside metal layers is shown, according to some embodiments. In various embodiments, vias for connecting to topside metal layer 210 are formed in the second step. For instance, in the illustrated embodiment, via 230B is formed to connect to routing 212A.

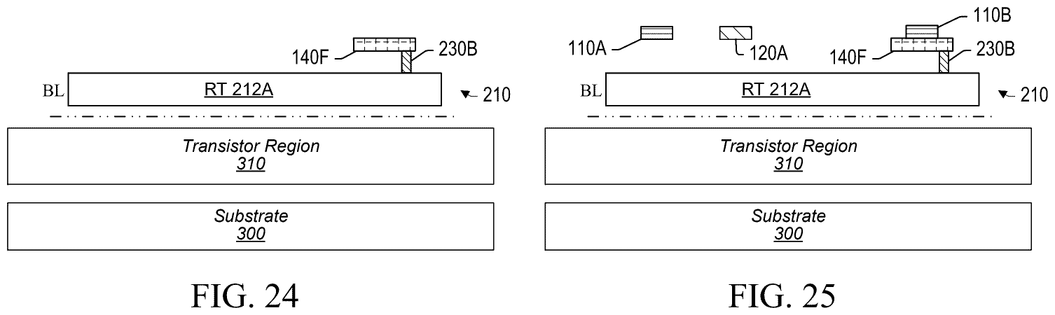

FIG. 24 depicts a cross-sectional side-view representation of a third manufacturing step of the memory circuit positioned between two topside metal layers, according to some embodiments. After forming vias to topside metal layer 210, in certain embodiments, the third step includes forming a layer of any source/drain regions for the memory circuits that are to be positioned below active regions of the memory circuit (e.g., lower source/drain regions). The source/drain regions may be connected to the vias formed in the previous (second) step. For instance, as shown in FIG. 24, source/drain region 140F is connected to via 230B.

FIG. 25 depicts a cross-sectional side-view representation of a fourth manufacturing step of the memory circuit positioned between two topside metal layers, according to some embodiments. In various embodiments, the fourth step includes formation of active regions. The active regions may include n-type active regions (e.g., active regions 110A, 110B) or p-type active regions (e.g., active region 120A). In various embodiments, the active regions are formed using thin channel materials such as, but not limited to, 2D (two-dimensional) materials, CNTs (carbon nano-tubes), and oxide semiconductors.

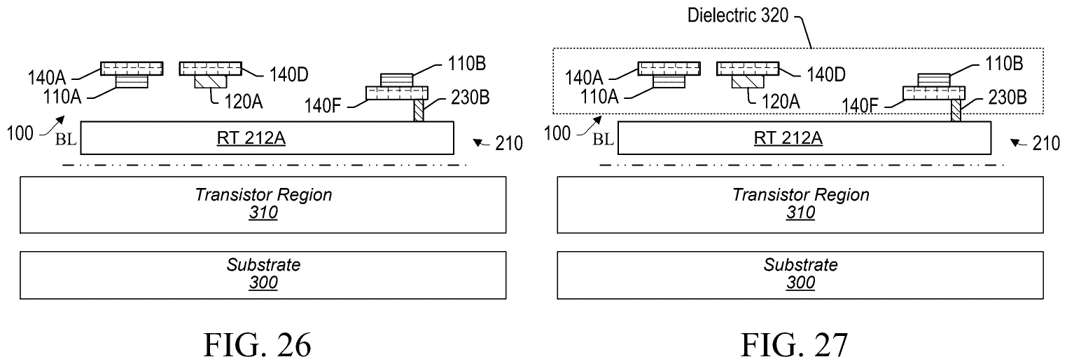

FIG. 26 depicts a cross-sectional side-view representation of a fifth manufacturing step of the memory circuit positioned between two topside metal layers, according to some embodiments. The fifth step may include the formation of source/drain regions vertically above the active regions (e.g., upper source/drain regions). For instance, in the illustrated embodiment, the fifth step includes formation of source/drain regions 140A, 140D above n-type active region 110A and p-type active region 120A, respectively. In certain embodiments, memory circuit 100 is substantially complete with the formation of source/drain regions above the active regions, as shown in FIG. 26. For instance, memory circuit 100 is largely complete except for additional connections to the upper source/drain regions.

FIG. 27 depicts a cross-sectional side-view representation of a sixth manufacturing step of the memory circuit positioned between two topside metal layers, according to some embodiments. In some embodiments, as shown in FIG. 27, this step includes enclosing the already formed components of memory circuit 100 inside dielectric 320. Enclosing the components inside dielectric 320 may include, for example, embedding or molding the components inside the dielectric material. While dielectric 320 is shown in the illustrated embodiment as being formed in a single step, some embodiments may be contemplated where the dielectric is added in layers. For instance, dielectric 320 may be formed in layers enclosing the components of memory circuit 100 as they are formed in each of the steps shown in FIGS. 23-26.

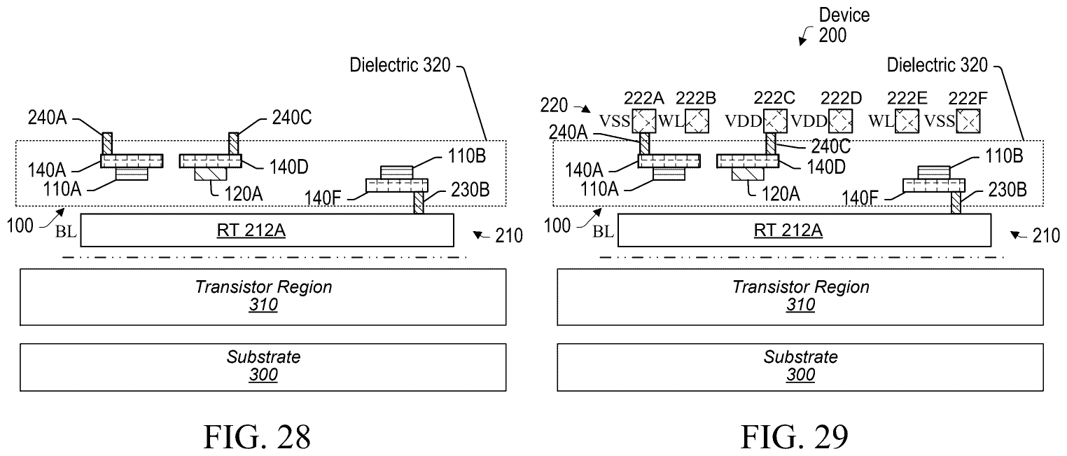

In some embodiments, after dielectric 320 encloses memory circuit 100, vias are formed to the upper source/drain regions of the memory circuit through the dielectric. FIG. 28 depicts a cross-sectional side-view representation of a seventh manufacturing step of the memory circuit positioned between two topside metal layers, according to some embodiments. In the seventh step, via 240A and via 240C are formed through dielectric 320 to source/drain region 140A and source/drain region 140D, respectively. While FIG. 28 illustrates the vias being formed after dielectric 320 is formed, it should be noted that some embodiments may be contemplated where the vias are formed before memory circuit 100 is enclosed in the dielectric (e.g., the steps of FIG. 27 and FIG. 28 may be reversed).

FIG. 29 depicts a cross-sectional side-view representation of a final (eighth) manufacturing step of the memory circuit positioned between two topside metal layers, according to some embodiments. In the substantially final step of formation of memory circuit 100, topside metal layer 220 is formed above the memory circuit with the specific routings in the topside metal layer coupled to the memory circuit by vias 240. For instance, in the illustrated embodiment, routing 222A (e.g., VSS routing) is connected to source/drain region 140A by via 240A and routing 222C (e.g., VDD routing) is connected to source/drain region 140A by via 240C. As described herein, topside metal layer 220 is a next topside metal layer after topside metal layer 210 (e.g., topside metal layer 220 is the topside metal layer next furthest from transistor region 310 after topside metal layer 210). Thus, memory circuit 100 is formed between topside metal layer 210 and topside metal layer 220 by the steps shown in FIGS. 23-29.

Note that similar steps for forming any of the memory circuits described herein may be implemented based on the illustrated steps shown in FIGS. 22-29. Further, it should be noted that these steps may also form the basis of any process for forming a memory circuit that has a middle topside metal layer in the memory circuit (e.g., middle metal layer 1710, shown in FIGS. 17-21).

### Example Computer System

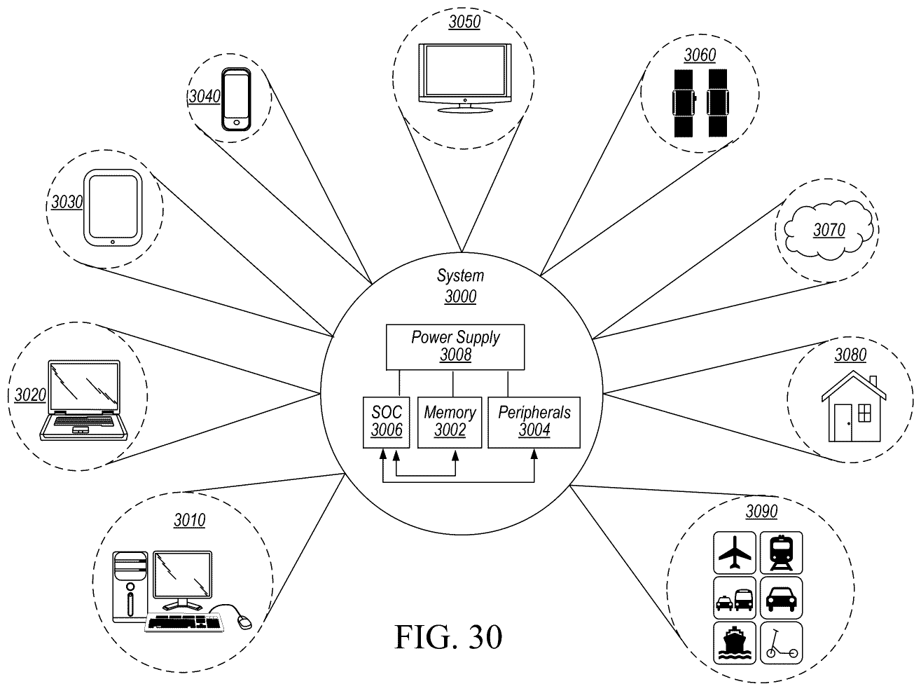

Turning next to FIG. 30, a block diagram of one embodiment of a system 3000 is shown that may incorporate and/or otherwise utilize the methods and mechanisms described herein. In the illustrated embodiment, the system 3000 includes at least one instance of a system on chip (SoC) 3006 which may include multiple types of processing units, such as a central processing unit (CPU), a graphics processing unit (GPU), or otherwise, a communication fabric, and interfaces to memories and input/output devices. In some embodiments, one or more processors in SoC 3006 includes multiple execution lanes and an instruction issue queue. In various embodiments, SoC 3006 is coupled to external memory 3002, peripherals 3004, and power supply 3008.

A power supply 3008 is also provided which supplies the supply voltages to SoC 3006 as well as one or more supply voltages to the memory 3002 and/or the peripherals 3004. In various embodiments, power supply 3008 represents a battery (e.g., a rechargeable battery in a smart phone, laptop or tablet computer, or other device). In some embodiments, more than one instance of SoC 3006 is included (and more than one external memory 3002 is included as well).

The memory 3002 is any type of memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR2, etc.), RAMBUS DRAM (RDRAM), static RAM (SRAM), etc. One or more memory devices are coupled onto a circuit board to form memory modules such as single inline memory modules (SIMMs), dual inline memory modules (DIMMs), etc. Alternatively, the devices are mounted with a SoC or an integrated circuit in a chip-on-chip configuration, a package-on-package configuration, or a multi-chip module configuration.

The peripherals 3004 include any desired circuitry, depending on the type of system 3000. For example, in one embodiment, peripherals 3004 includes devices for various types of wireless communication, such as Wi-Fi, Bluetooth, cellular, global positioning system, etc. In some embodiments, the peripherals 3004 also include additional storage, including RAM storage, solid state storage, or disk storage. The peripherals 3004 include user interface devices such as a display screen, including touch display screens or multitouch display screens, keyboard or other input devices, microphones, speakers, etc.

As illustrated, system 3000 is shown to have application in a wide range of areas. For example, system 3000 may be utilized as part of the chips, circuitry, components, etc., of a desktop computer 3010, laptop computer 3020, tablet computer 3030, cellular or mobile phone 3040, or television 3050 (or set-top box coupled to a television). Also illustrated is a smartwatch and health monitoring device 3060. In some embodiments, smartwatch may include a variety of general-purpose computing related functions. For example, smartwatch may provide access to email, cellphone service, a user calendar, and so on. In various embodiments, a health monitoring device may be a dedicated medical device or otherwise include dedicated health related functionality. For example, a health monitoring device may monitor a user's vital signs, track proximity of a user to other users for the purpose of epidemiological social distancing, contact tracing, provide communication to an emergency service in the event of a health crisis, and so on. In various embodiments, the above-mentioned smartwatch may or may not include some or any health monitoring related functions. Other wearable devices are contemplated as well, such as devices worn around the neck, devices that are implantable in the human body, glasses designed to provide an augmented and/or virtual reality experience, and so on.

System 3000 may further be used as part of a cloud-based service(s) 3070. For example, the previously mentioned devices, and/or other devices, may access computing resources in the cloud (i.e., remotely located hardware and/or software resources). Still further, system 3000 may be utilized in one or more devices of a home 3080 other than those previously mentioned. For example, appliances within the home may monitor and detect conditions that warrant attention. For example, various devices within the home (e.g., a refrigerator, a cooling system, etc.) may monitor the status of the device and provide an alert to the homeowner (or, for example, a repair facility) should a particular event be detected. Alternatively, a thermostat may monitor the temperature in the home and may automate adjustments to a heating/cooling system based on a history of responses to various conditions by the homeowner. Also illustrated in FIG. 30 is the application of system 3000 to various modes of transportation 3090. For example, system 3000 may be used in the control and/or entertainment systems of aircraft, trains, buses, cars for hire, private automobiles, waterborne vessels from private boats to cruise liners, scooters (for rent or owned), and so on. In various cases, system 3000 may be used to provide automated guidance (e.g., self-driving vehicles), general systems control, and otherwise. These any many other embodiments are possible and are contemplated. It is noted that the devices and applications illustrated in FIG. 30 are illustrative only and are not intended to be limiting. Other devices are possible and are contemplated.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, circuit, a system having a processor unit and a memory storing program instructions executable to implement the task, etc. This phrase is not used herein to refer to something intangible.

In some cases, various units/circuits/components may be described herein as performing a set of task or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements defined by the functions or operations that they are configured to implement. The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. An apparatus, comprising:
a transistor region of an integrated circuit, the transistor region being above a substrate in a vertical dimension perpendicular to the substrate;
a first metal layer located above the transistor region in the vertical dimension, the first metal layer having power supply routing, ground supply routing, and wordline routing oriented along a first direction in a horizontal dimension;
a second metal layer located above the transistor region in the vertical dimension, the second metal layer having bitline routing oriented along a second direction in the horizontal dimension, the second direction being orthogonal to the first direction; and
a memory circuit positioned between the first metal layer and the second metal layer in the vertical dimension, wherein the memory circuit includes:
a plurality of active regions including at least one active region of a first type and at least one active region of a second type;
a plurality of transistors having gates and source/drain regions formed over the plurality of active regions; and
a plurality of vias, wherein the plurality of vias includes at least:
a first via coupling a first source/drain region to the bitline routing;
a second via coupling a gate to the wordline routing;
a third via coupling a second source/drain region to the power supply routing; and
a fourth via coupling a third source/drain region to the ground supply routing.

2. The apparatus of claim 1, wherein the at least one active region of the first type is an n-type active region, and wherein the at least one active region of the second type is a p-type active region.

3. The apparatus of claim 1, wherein the first metal layer is above the second metal layer in the vertical dimension.

4. The apparatus of claim 1, wherein the first metal layer is below the second metal layer in the vertical dimension.

5. The apparatus of claim 1, wherein the active regions lie in a single plane between the first metal layer and the second metal layer in the vertical dimension.

6. The apparatus of claim 1, wherein the at least one active region of the first type is stacked above the at least one active region of the second type in the vertical dimension.

7. The apparatus of claim 1, wherein the gates and the source/drain regions are positioned above or below the active regions in the vertical dimension.

8. The apparatus of claim 1, wherein a gate of at least one transistor is coupled to a source/drain region of at least one additional transistor.

9. The apparatus of claim 1:
wherein the plurality of active regions includes:
a first active region of the first type positioned on a first side of the memory circuit in the horizontal dimension;
a second active region of the first type positioned on a second side of the memory circuit in the horizontal dimension;
a third active region of the second type positioned on the first side of the memory circuit in the horizontal dimension; and
a fourth active region of the second type positioned on the second side of the memory circuit in the horizontal dimension;
wherein the plurality of transistors includes:
a first transistor having a gate and source/drain regions formed over the first active region;
a second transistor having a gate and source/drain regions formed over the first active region;
a third transistor having a gate and source/drain regions formed over the second active region;
a fourth transistor having a gate and source/drain regions formed over the second active region;
a fifth transistor having a gate and source/drain regions formed over the third active region; and
a sixth transistor having a gate and source/drain regions formed over the fourth active region.

10. The apparatus of claim 9, wherein the gate of the first transistor is coupled to the gate of the fifth transistor and the gate of the third transistor is coupled to the gate of the sixth transistor, wherein the first transistor and the second transistor share a source/drain region that is coupled to a source/drain region of the fifth transistor, wherein the third transistor and the fourth transistor share a source/drain region that is coupled to a source/drain region of the sixth transistor, and wherein the gate of the fifth transistor is coupled to the source/drain region of the sixth transistor and the gate of the sixth transistor is coupled to the source/drain region of the fifth transistor.

11. The apparatus of claim 9, wherein the third and fourth active regions are positioned between the first and second active regions in the horizontal dimension.

12. The apparatus of claim 9, wherein the third active region is positioned above or below the first active region in the vertical dimension, and wherein the fourth active region is positioned above or below the second active region in the vertical dimension.

13. An apparatus, comprising:
a transistor circuit positioned within a transistor region of an integrated circuit, the transistor being above a substrate in a vertical dimension perpendicular to the substrate;
a first metal layer located above the transistor circuit in the vertical dimension, the first metal layer having power supply routing, ground supply routing, and wordline routing oriented along a first direction in a horizontal dimension;
a second metal layer located above the transistor circuit in the vertical dimension, the second metal layer having bitline routing oriented along a second direction in the horizontal dimension, the second direction being orthogonal to the first direction; and
a memory circuit positioned between the first metal layer and the second metal layer in the vertical dimension, wherein the memory circuit includes:
a first n-type active region;
a second n-type active region displaced from the first n-type active region in the horizontal dimension;
a first p-type active region;
a second p-type active region displaced from the first p-type active region in the horizontal dimension;
a set of at least four transistors having gates and source/drain regions formed over the active regions, wherein the gates and the source/drain regions are interconnected to form the memory circuit; and
a plurality of vias coupling the transistors to the bitline routing, the wordline routing, the power supply routing, and the ground supply routing.

14. The apparatus of claim 13, wherein the plurality of vias includes at least:
a first via coupling a source/drain region over one of the n-type active regions to the bitline routing;
a second via coupling a gate over one of the n-type active regions to the wordline routing;
a third via coupling a source/drain region over one of the p-type active regions to the power supply routing; and
a fourth via coupling a source/drain region over one of the n-type active regions to the ground supply routing.

15. The apparatus of claim 13, wherein the first and second p-type active regions are positioned between the first and second n-type active regions in the horizontal dimension.

16. The apparatus of claim 13, wherein the first p-type active region is positioned above or below the first n-type active region in the vertical dimension, and wherein the second p-type active region is positioned above or below the second n-type active region in the vertical dimension.

17. An apparatus, comprising:
a transistor region of an integrated circuit, the transistor region being above a substrate in a vertical dimension perpendicular to the substrate;
a first metal layer located above the transistor region in the vertical dimension, the first metal layer having ground supply routing and wordline routing oriented along a first direction in a horizontal dimension;
a second metal layer located above the transistor region in the vertical dimension, the second metal layer having power supply routing oriented along the first direction in the horizontal dimension;
a third metal layer located above the transistor region in the vertical dimension, the third metal layer having bitline routing oriented along a second direction in the horizontal dimension, the second direction being orthogonal to the first direction; and
a memory circuit positioned between the first metal layer and the second metal layer in the vertical dimension, wherein the memory circuit includes:
a plurality of active regions including at least one active region of a first type and at least one active region of a second type;
a plurality of transistors having gates and source/drain regions formed over the plurality of active regions; and
a plurality of vias, wherein the plurality of vias includes at least:
a first via coupling a first source/drain region to the bitline routing;
a second via coupling a gate to the wordline routing;
a third via coupling a second source/drain region to the power routing; and
a fourth via coupling a third source/drain region to the ground routing.

18. The apparatus of claim 17, wherein the third metal layer is positioned between the first and second metal layers and between the at least one active region of the first type and at least one active region of the second type.

19. The apparatus of claim 17, wherein a gate of at least one transistor is coupled to a source/drain region of at least one additional transistor through additional routing in the third metal layer.

20. The apparatus of claim 17, wherein the at least one active region of the first type lies in a plane displaced in the vertical dimension from a plane the at least one active region of the second type lies in.
